(19) United States
(12) Patent Application Publication
(10) Pub. No.: US 2010/0193884 A1
(43) Pub. Date: Aug. 5, 2010

(54) Method of Fabricating High Aspect Ratio Transducer Using Metal Compression Bonding

(76) Inventors: Woo Tae Park, Chandler, AZ (US); Heinz Loreck, Tempe, AZ (US); Lisa Karlin, Chandler, AZ (US)

Correspondence Address: HAMILTON & TERRILE, LLP - FREESCALE, P.O. BOX 203518, AUSTIN, TX, 78720, US

(21) Appl. No.: 12/363,916

(22) Filed: Feb. 2, 2009

(51) Int. Cl. B81B 7/02; H01L 21/00; H01L 21/603; H01L 21/302; H01L 29/84; G01P 15/02

(52) U.S. Cl. 257/414; 438/51; 438/456; 438/690; 73/504.02; 257/E29.324; 257/E21.519

(57) ABSTRACT

A method and apparatus are described for fabricating a high aspect ratio MEMS device by using metal thermocompression bonding to assemble a reference wafer (100), a bulk MEMS active wafer (200), and a cap wafer (300) to provide a proof mass (200d) formed from the active wafer with bottom and top capacitive sensing electrodes (115, 315) which are hermetically sealed from the ambient environment by sealing ring structures (112/202/200a/212/312 and 116/206/200e/216/316).

### BACKGROUND OF THE INVENTION

1. Field of the Invention

The present invention is directed in general to the field of semiconductor devices. In one aspect, the present invention relates to MEMS devices and methods for fabricating MEMS devices.

2. Description of the Related Art

Micro-Electro-Mechanical Systems (MEMS) technology is increasingly used to integrate mechanical elements, sensors, actuators, and electronics on a common silicon substrate through microfabrication technology. For example, inertial sensors may be formed with MEMS devices on an integrated circuit wafer substrate to form various applications, such as a MEMS gyroscope that is used to measure an angular rate of an object. With conventional deposition-based fabrication techniques, a MEMS gyroscope is constructed from a silicon-on-insulator wafer that includes a substrate layer, a sacrificial layer overlying the substrate layer, and an active layer overlying the sacrificial layer, where trenches are etched into the active layer and, in some cases, undercut the active layer, to form among other component parts, a proof mass and capacitive elements. The proof mass is resiliently suspended by one or more suspension springs and capable of moving along one or more of at least three orthogonal axes when the MEMS gyroscope experiences a rotation at a sensitive axis. The capacitive elements sense displacement of the proof mass, and the displacement is converted into an electrical signal having a parameter magnitude relating to angular rate. While the deposition-based fabrication techniques have reduced the costs for making MEMS gyroscopes, there are difficulties associated with the various fabrication steps needed to build up the sensor component parts, including controlling the accuracy of the pattern and etch processes (e.g., in terms of the location, depth and width of etch openings) and the deposition processes (e.g., in terms of the location, thickness and width of defined features), as well as the structural integrity of the various sensor component parts. The deposition-based fabrication techniques are also not well suited for forming high aspect ratio micro-electromechanical system (HARMEMS) devices which provide out-of-plane sensing and actuation performance. With some exceptions, most deposition fabrication techniques require long deposition times for thick layers. And it is also difficult to control stress in the deposited layers. As an alternative to deposition-based fabrication techniques, bonding-based fabrication techniques have been used to form a MEMS sensor by bonding a gyroscope wafer between a reference wafer and a cap wafer with a high temperature metal bonding process. However, these sensors have limited out-of-plane sensitivity due to limited electrode placement.

Accordingly, a need exists for a high quality, reliable HARMEMS device and manufacture method therefore which overcomes the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a simplified cross section view of a MEMS device which includes a high aspect ratio MEMS transducer with out-of-plane sensing electrodes integrated with the handle wafer and cap wafers that are bonded together using metal compression bonding;

FIGS. 2-12 are simplified cross section views of the MEMS device shown in FIG. 1 to illustrate various exemplary fabrication steps for making the MEMS device in accordance with selected embodiments of the present invention; and

FIG. 13 is a simplified cross section view of a MEMS device which includes a high aspect ratio MEMS transducer with out-of-plane sensing electrodes integrated with the handle wafer and cap wafers that are bonded together in accordance with selected alternative embodiments.

### DETAILED DESCRIPTION

A method and apparatus are described for fabricating a high aspect ratio transducer using metal compression bonding to affix an active wafer to a reference wafer and a cap wafer. In selected embodiments, a first patterned layer of aluminum is formed on a monocrystalline silicon reference wafer to define electrode, interconnect, and bond ring structures. In addition, a second patterned layer of aluminum is formed on a first surface of a monocrystalline silicon active wafer to define aligned interconnect and bond ring structures so that the interconnect and bond ring structures on the active wafer and reference wafer can be aligned and bonded together using metal compression bonding techniques. After compression bonding the reference wafer to the active wafer, a third patterned layer of aluminum is formed on a second, opposite surface of the active wafer to define aligned interconnect and bond ring structures, or alternatively, a patterned layer of germanium is formed on the second, opposite surface of the active wafer to define aligned interconnect and bond ring structures. In either case, the active wafer is subsequently etched to form one or more MEMS sensor elements, interconnect structures, and bond ring structures. After etching the active wafer, a monocrystalline silicon cap wafer is provided which includes a fourth patterned layer of aluminum to define aligned electrode, interconnect, and bond ring structures. As formed, the cap wafer may be implemented as an application specific integrated circuit for driving and sensing motion of the subsequently-formed MEMS sensor elements. The aligned interconnect and bond ring structures on the active wafer and cap wafer can be bonded together using metal thermocompression bonding techniques when the structures are formed with metal, or can be bonded together using a eutectic bonding technique when the structures are formed with other appropriate materials (e.g., gold and tin (Au—Sn), gold and germanium (Au—Ge), and gold and silicon (Au—Si)). In this way, MEMS sensor elements (such as an accelerometer or gyroscope) are fabricated from the active wafer that is affixed to and hermetically sealed by the reference wafer and cap wafer such that the active wafer is sandwiched in between and protected by the cap wafer and the reference wafer. In addition, by forming the bottom electrodes, interconnects and anchors with patterned metal (e.g., aluminum), metal bonding techniques can be used to seal the MEMS sensor elements between the reference and cap wafers, thereby providing a hermetic seal that is superior to oxide or glass sealing techniques.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, it is noted that, throughout this detailed description, certain layers of materials will be deposited and removed to form the depicted semiconductor structures. Where the specific procedures for depositing or removing such layers are not detailed below, conventional techniques to one skilled in the art for depositing, removing or otherwise forming such layers at appropriate thicknesses shall be intended. Such details are well known and not considered necessary to teach one skilled in the art of how to make or use the present invention. In addition, selected aspects are depicted with reference to simplified cross sectional drawings of a semiconductor device without including every device feature or geometry in order to avoid limiting or obscuring the present invention. Such descriptions and representations are used by those skilled in the art to describe and convey the substance of their work to others skilled in the art. It is also noted that, throughout this detailed description, certain elements in the figures are illustrated for simplicity and clarity and have not necessarily been drawn to scale. For example, the dimensions of some of the elements in the figures may be exaggerated relative to other elements to help improve the understanding of the embodiments of the present invention.

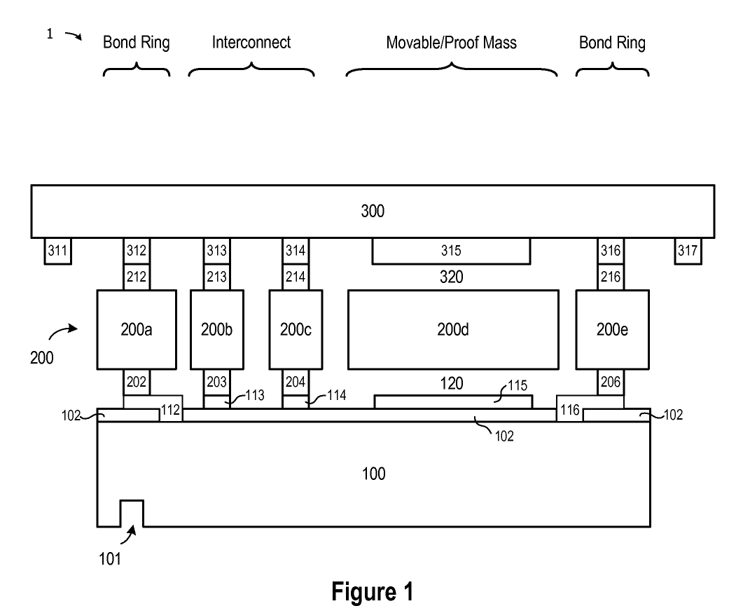

Referring now to FIG. 1, there is shown a simplified cross section view of a MEMS device 1. The depicted MEMS device 1 is an inertial sensor that includes a single sensor that formed with a high aspect ratio MEMS proof mass 200d and two out-of-plane sensing electrodes 115, 315 that are integrated with the handle wafer structure 100 and cap wafer structure 300, respectively, where the handle and cap wafers are bonded together using metal compression bonding techniques. As will be appreciated, a single sensor is shown that represents any type of MEMS sensor (such as an accelerometer, a gyroscope, etc.), but any number of MEMS sensor devices could be formed in the active wafer layer 200. The depicted sensor includes a MEMS proof mass 200d that is suspended above the handling wafer substrate 100 by, for example, one or more suspension springs (not shown), thereby defining a cavity 120. In addition, the depicted sensor includes one or more interconnect structures 200b, 200c formed in the active wafer layer 200 which are fixedly coupled to the handling wafer substrate 100 (by the metal bond anchor elements 113/203, 114/204) and to the cap wafer substrate 300 (by the metal bond anchor elements 213/313, 214/314). These interconnect structures 200b, 200c also act as a mechanical anchor of the proof mass 200d to the surrounding frame. The depicted sensor also includes bond ring structures 200a, 200e which are formed in the active wafer layer 200 and fixedly coupled to the handling wafer substrate 100 (by the metal bond anchor elements 112/202, 116/206) and to the cap wafer substrate 300 (by the metal bond anchor elements 212/312, 216/316). The depicted MEMS device 1 may also include one or more non-illustrated moving electrodes and one or more non-illustrated fixed electrodes. The moving electrodes may form part of the suspended sensor structure 200d, and the fixed electrodes may be fixedly coupled to the handling wafer substrate 100. The specific structure and configuration of the MEMS sensor may vary. Moreover, a description of the specific structure and configuration of the MEMS sensor is not needed to enable or fully describe the present invention, and will thus not be further described in more detail.

The MEMS device 1 includes a protective cap wafer structure 300 which is fixedly coupled to the handling wafer substrate 100, and which extends over at least the suspended sensor structures 200d to provide physical protection thereof. It will be appreciated that the protective cap wafer structure 300 may also extend over the entire sensor structure, both suspended and non-suspended portions. The patterned metal layer on the protective cap wafer structure 300 includes not only an aligned upper electrode structure 315, interconnect structures 313, 314, and bond ring structures 312, 316, but also includes bond pad structures 311, 317 for making electrical contact to external signals and/or supply voltage(s). The protective cap wafer structure 300 is spaced-apart from its suspended sensor structure 200d to define a cavity 320. As will be described more fully below, the active layer 200 is etched until the insulator layer 102 defines and releases the active layer at the same time, thereby avoiding the processing complexities associated with release etch processes.

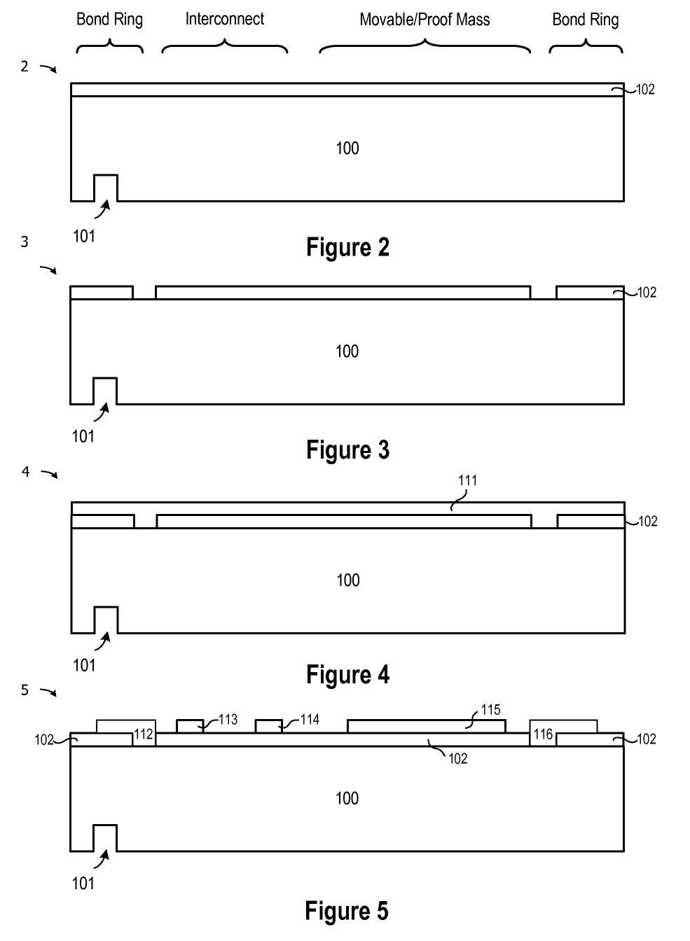

Having described an embodiment of a MEMS device 1 from a structural standpoint, an example process sequence for fabricating the MEMS device 1 will now be described with reference to FIGS. 2-12. While the depicted process sequence is provided with reference to making the MEMS device 1 shown in FIG. 1, it will be appreciated that the process is applicable to any one of numerous other MEMS devices, and that there are additional process steps (such as the specific process steps for fabricating the anti-stiction dimple) that are not be described, as these may be formed using any one of numerous processes, now known or developed in the future. Moreover, although for convenience the method is described using a particular order of steps, portions of the method could be performed in a different order or using different types of steps than what is described below.

FIGS. 2-5 schematically illustrate the formation of the reference or handling wafer structure 100. Referring now to FIG. 2, there is shown a partial cross-sectional view of a handling wafer structure 2. In particular, the handling wafer structure 2 includes a first substrate 100. Depending on the type of device being fabricated, the first substrate 100 may be implemented with monocrystalline semiconductor material, such as a bulk insulator substrate, a bulk metal substrate, a bulk silicon substrate, single crystalline silicon (doped or undoped), semiconductor-on-insulator (SOI) substrate, a multi-layered composite film wafer substrate or any semiconductor material including, for example, Si, SiC, SiGe, SiGeC, Ge, GaAs, InAs, InP as well as other Group III-IV compound semiconductors or any combination thereof The first substrate 100 is patterned with one or more backside alignment marks 101. Though not shown, the alignment mark(s) 101 can be formed by patterning a first etch mask (M1) and the applying a reactive ion etching (RIE) process, though any desired marking process can be used.

After forming the backside alignment mark(s) 101, an insulator layer 102 is formed (e.g. grown or deposited) on the first substrate 100. In selected embodiments, the surface of the first substrate 100 facing away from alignment marks 101 is cleaned and a thin (e.g., 2 um) layer of oxide is thermally grown to passivate the first substrate 100 and to serve an etch stop for future structural silicon etch processing (described hereinbelow). Thus, the insulator layer 102 may be implemented as silicon dioxide or some low-k dielectric material, but may include other materials such as, e.g. PSG, FSG, silicon nitride, and/or other types of dielectric, including low-K dielectric materials with high thermal conductivity for cooling.

FIG. 3 illustrates processing of a semiconductor wafer structure 3 subsequent to FIG. 2 after the insulator layer 102 is patterned and etched to form openings that expose the first substrate 100. Though not shown, a second patterned masking layer (M2) may be formed over the insulator layer 102, and any desired etching technique may be used to form the opening in the insulator layer 102 that expose the first substrate 100. As shown in the subsequent figures, the openings in the insulator layer 102 define grounding contact regions to the first substrate 100 for the bond ring structures 112, 116 in the bond ring area.

FIG. 4 which illustrates processing of a semiconductor wafer structure 4 subsequent to FIG. 3 after a first metal layer 111 is deposited on the semiconductor wafer structure 4. In selected embodiments, the first metal layer 111 is deposited on the patterned insulator layer 102 and exposed first substrate 100 using any desired deposition or sputtering process, such as chemical vapor deposition (CVD), plasma-enhanced chemical vapor deposition (PECVD), physical vapor deposition (PVD), atomic layer deposition (ALD), molecular beam deposition (MBD) or any combination(s) thereof. A suitable material for use as the first metal layer 111 is aluminum which may be deposited to a predetermined thickness of less than 5 microns (e.g., 2-4 microns), though other metals with different thicknesses may be used.

FIG. 5 illustrates processing of a semiconductor wafer structure 5 subsequent to FIG. 4 after the deposited first metal layer 111 is patterned and etched to define electrode, interconnect, and bond ring structures on the first substrate 100. In particular, a third patterned resist or mask layer (M3) (not shown) is formed on the deposited first metal layer 111 to substantially protect the patterned insulator layer 102, and the exposed portions of the first metal layer 111 are selectively etched and removed, thereby leaving portions of the first metal layer 111, including the electrode structure 115 in the movable mass or proof mass area, the interconnect structures 113, 114 in the interconnect area, and the bond ring structures 112, 116 in the bond ring area. The pattern transfer and etching of the first metal layer 111 may use one or more etching steps to remove the unprotected portions of the first metal layer 111, including a dry etching process such as reactive-ion etching, ion beam etching, plasma etching or laser etching, a wet etching process wherein a chemical etchant is employed or any combination thereof.

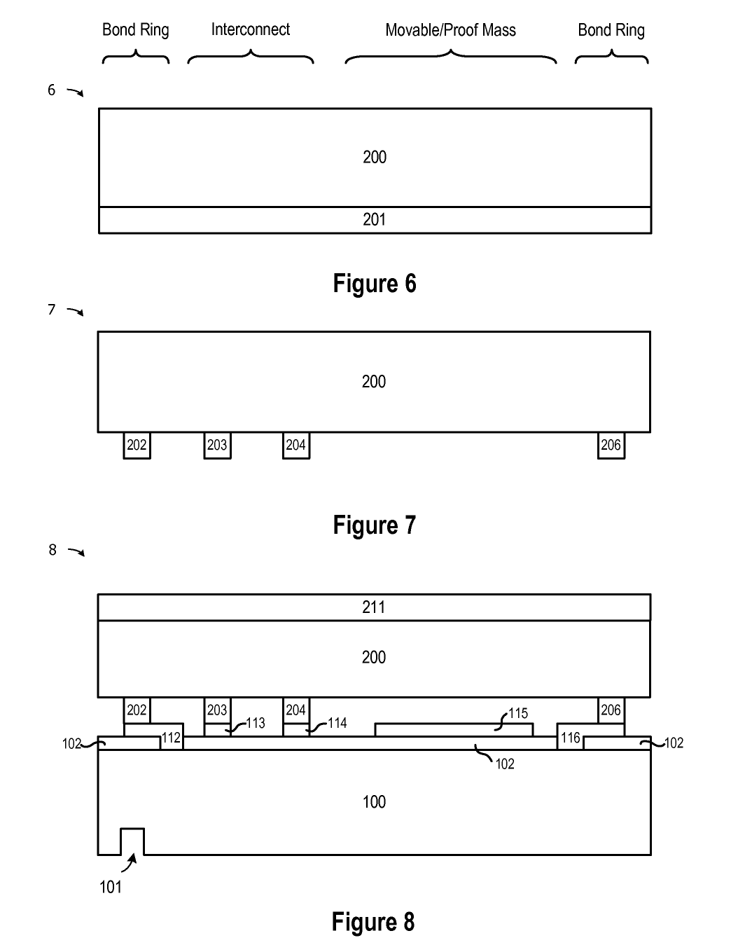

FIGS. 6-7 schematically illustrate the formation of the active wafer structure 200. Referring now to FIG. 6, there is shown a partial cross-sectional view of an active wafer structure 6 which includes a second substrate 200. Depending on the type of device being fabricated, the second substrate 200 may be implemented with monocrystalline semiconductor material, such as a bulk insulator substrate, a bulk metal substrate, a bulk silicon substrate, single crystalline silicon (doped or undoped), semiconductor-on-insulator (SOI) substrate, a multi-layered composite film wafer substrate or any semiconductor material including, for example, Si, SiC, SiGe, SiGeC, Ge, GaAs, InAs, InP as well as other Group III-IV compound semiconductors or any combination thereof. In addition, a second metal layer 201 (e.g., aluminum) is deposited on the second substrate 200 using any desired deposition or sputtering process to a predetermined thickness (e.g., 2-4 microns), though other metals with different thicknesses may be used.

FIG. 7 illustrates processing of a semiconductor wafer structure 7 subsequent to FIG. 6 after the second metal layer 201 is patterned and etched to define electrode, interconnect, and bond ring structures on the second substrate 200. For example, a fourth patterned resist or mask layer (M4) (not shown) is formed on the deposited second metal layer 201, and the exposed portions of the second metal layer 201 are selectively etched and removed, thereby leaving portions of the second metal layer 201, including the interconnect structures 203, 204 in the interconnect area, and the bond ring structures 202, 206 in the bond ring areas. The pattern transfer and etching of the second metal layer 201 may use one or more etching steps to remove the unprotected portions of the second metal layer 201, including a dry etching process such as reactive-ion etching, ion beam etching, plasma etching or laser etching, a wet etching process wherein a chemical etchant is employed or any combination thereof.

FIG. 8 illustrates processing of a semiconductor wafer structure 8 subsequent to FIG. 7 after the handling wafer structure 100 and active wafer structure 200 have been bonded together and a third metal layer 211 is formed on the top surface of the active wafer structure 200. In preparation for bonding, the handling wafer structure 100 and the active wafer structure 200 may each be cleaned, such as by using an non-oxidizing ash chemistry or solvent-based wet removal process which does not oxidize the underlying metal layers. In selected embodiments, the handling wafer structure 100 and active wafer structure 200 are bonded together using metal compression bonding techniques, such as a combination of thermal and pressure bonding. For example, when the metal bond anchor elements 112-116 and 202-204 and 206 are formed with patterned aluminum, the aluminum layers are bonded together using thermocompression bonding whereby the anchor elements are aligned in contact while heat and compression is applied to bond the aligned anchor elements to one another. As will be appreciated, thermocompression bonding may be implemented by applying pressure at or above a predetermined threshold (e.g., 30 MPa) in combination with a relatively low temperature heat processs (e.g., at or below 500 degrees Celsius). For example, aluminum thermocompression bonding may be implemented by aligning and compressing the handling wafer structure 100 and active wafer structure 200 with 70-90 kiloNewtons of force while heating the wafer structures 100, 200 to 400-500 degrees Celsius for approximately 30-50 minutes. By attaching the handling wafer structure 100 to the active wafer structure 200 using a metal-to-metal bond technique, the MEMS transducer structures formed from the active wafer structure 200 can be hermetically sealed by the bonding rings 112/202 and 116/206.

Either before or after bonding the handling and active wafer structures, the active wafer structure 200 may be thinned to a thickness of about 25 microns, or to any desired thickness that allows a high aspect ratio MEMS transducer elements to be formed therefrom. This is shown in FIG. 8 by the reduced thickness of the active wafer structure 200. Conventional grinding and polishing is a suitable method for performing this thinning step. The thinning of active wafer structure 200 can be done uniformly, or it can be done so that regions of active wafer 200 that will become MEMS transducer elements (e.g., different proof masses) are thicker than other parts of active wafer 200. After thinning the active wafer 200, a third metal layer 211 (e.g., aluminum) is deposited on the second substrate 200 using any desired deposition or sputtering process to a predetermined thickness (e.g., 2-4 microns), though other metals with different thicknesses may be used.

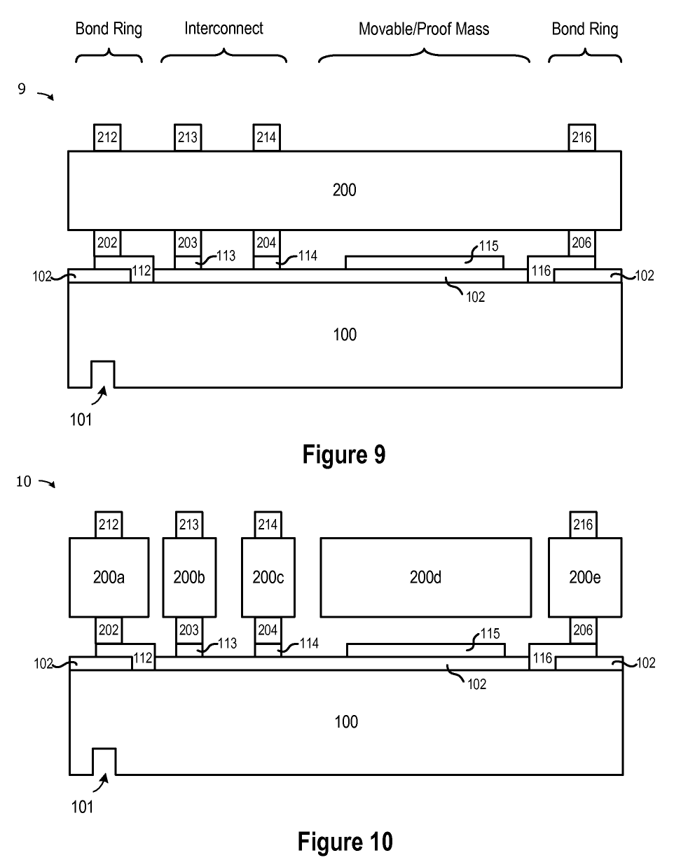

FIG. 9 illustrates processing of a semiconductor wafer structure 9 subsequent to FIG. 8 after the deposited third metal layer 211 is patterned and etched to define interconnect and bond ring structures on the second substrate 200. In particular, a fifth patterned resist or mask layer (M5) (not shown) is formed on the deposited third metal layer 211, and the exposed portions of the third metal layer 211 are selectively etched and removed, thereby leaving portions of the third metal layer 211, including the interconnect structures 213, 214 in the interconnect area, and the bond ring structures 212, 216 in the bond ring areas. The pattern transfer and etching of the third metal layer 211 may use any desired etching steps to remove the unprotected portions of the third metal layer 311.

FIG. 10 illustrates processing of a semiconductor wafer structure 10 subsequent to FIG. 9 after the second substrate in the active wafer structure 200 is selectively etched to form the interconnect and bond ring structures, as well as the MEMS transducer elements, such as any mechanical elements in the MEMS sensor (e.g., a gyroscope sensor). For example, a sixth patterned resist or mask layer (M6) (not shown) may be formed to protect the etched third metal layer 211 and expose portions of the second substrate 200, and the exposed portions of the second substrate 200 are selectively etched and removed with a deep reactive ion etch (DRIE) process. While the second substrate layer 200 may be structurally etched using a DRIE process to define the active layer elements 200a-200e, it will be appreciated that any desired pattern and etching processes may be used, including application and patterning of photoresist directly on the active wafer structure 200. In selected embodiments, the structural etch process is selected that is suitable for creating high-aspect ratio features. After the structural etch of the active wafer structure 200 is performed, all of the component parts of the MEMs sensor device are formed. These component parts include the interconnect structures 200b, 200c which are fixedly coupled to the handling wafer structure 100 and may implement any desired sensor circuit function, such as a sense electrode or drive electrode function. The component parts also include the bond ring structures 200a, 200e which are fixedly coupled to the handling wafer structure 100. Finally, the component parts include the mechanical elements 200d of the MEMS sensor device, such as one or more proof mass structures, plates, flexures, frame, and hinges (not shown). For simplicity, FIG. 10 shows only the high aspect ratio MEMS transducer element 200d.

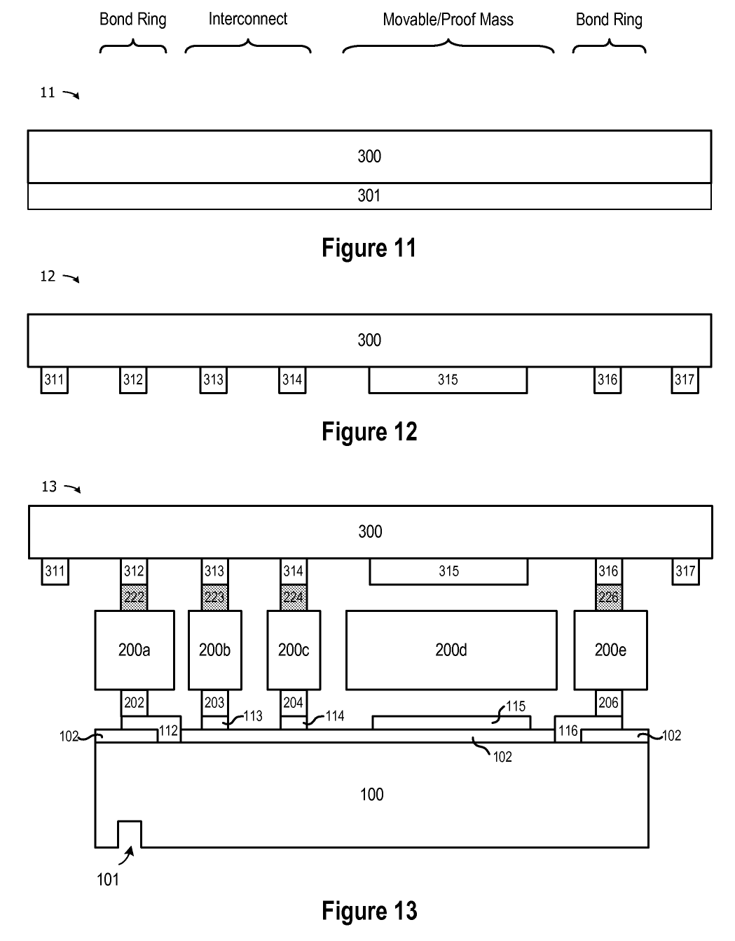

FIGS. 11-12 schematically illustrate the formation of the cap wafer structure 300. Referring now to FIG. 11, there is shown a partial cross-sectional view of a protective cap wafer structure 11 which includes a third substrate 300. Depending on the type of device being fabricated, the third substrate 300 may be implemented with monocrystalline semiconductor material, such as a bulk insulator substrate, a bulk metal substrate, a bulk silicon substrate, single crystalline silicon (doped or undoped), semiconductor-on-insulator (SOI) substrate, a multi-layered composite film wafer substrate or any semiconductor material including, for example, Si, SiC, SiGe, SiGeC, Ge, GaAs, InAs, InP as well as other Group III-IV compound semiconductors or any combination thereof. In addition, a fourth metal layer 301 (e.g., aluminum) is deposited on the third substrate 300 using any desired deposition or sputtering process to a predetermined thickness (e.g., 2-4 microns), though other metals with different thicknesses may be used.

FIG. 12 illustrates processing of a semiconductor wafer structure 12 subsequent to FIG. 11 after the fourth metal layer 301 is patterned and etched to define electrode, interconnect, bond ring, and bond pad structures on the third substrate 300. For example, a patterned resist or mask layer (M7) (not shown) is formed on the deposited fourth metal layer 301, and the exposed portions of the fourth metal layer 301 are selectively etched and removed, thereby leaving the bond pad structures 311, 317, interconnect structures 313, 314 in the interconnect area, and the bond ring structures 312, 316 in the bond ring areas. The pattern transfer and etching of the fourth metal layer 301 may use any desired etching steps to remove the unprotected portions of the fourth metal layer 301.

At this point, reference is made back to FIG. 1 which illustrates processing of a semiconductor wafer structure 13 subsequent to FIG. 12 after the protective cap wafer structure 300 is bonded to the active wafer structure 200 (which was previously bonded to the handling wafer structure 100. In preparation for bonding, the cap wafer structure 300 and the active wafer structure 200 may each be cleaned, such as by using an appropriate ash chemistry or solvent-based wet removal process. In selected embodiments, the protective cap wafer structure 300 and active wafer structure 200 are bonded together using metal compression bonding techniques, such as a combination of thermal and pressure bonding. For example, when the metal bond anchor elements 212-214 and 216 and 312-314 and 316 are formed with patterned aluminum, the aluminum layers are bonded together using thermocompression bonding whereby the anchor elements are aligned in contact while heat and compression is applied to bond the aligned anchor elements to one another. In this example, thermocompression bonding may be implemented by applying pressure at or above a predetermined threshold (e.g., 30 MPa) in combination with a relatively low temperature heat processs (e.g., at or below 500 degrees Celsius). By attaching the protective cap wafer structure 300 to the active wafer structure 200 using a metal-to-metal bond technique, the MEMS transducer structures formed from the active wafer structure 200 can be hermetically sealed by the bonding ring structures 112/202/200a/212/312 and 116/206/200c/216/316.

The metal thermocompression bonding techniques described hereinabove provide a hermetic barrier between the MEMS transducer structures (formed from the active wafer structure 200) and the ambient environment which is superior to the sealing performance provided by oxide or glass sealing techniques. However, it is contemplated that other bonding techniques may be used and still obtain the benefits described herein. For example, FIG. 13 is a simplified cross section view of a MEMS device 13 which is formed in accordance with selected alternative embodiments. The depicted MEMS device 13 is an inertial measurement unit that includes a high aspect ratio MEMS transducer 200d and two out-of-plane sensing electrodes 115, 315 that are integrated with the handle wafer structure 100 and cap wafer structure 300, substantially as described hereinabove with reference to FIGS. 2-12. However, instead of using thermocompression bonding techniques to bond the aligned metal bond anchor elements 212-214 and 216 to the aligned metal bond anchor elements 312-314 and 316, the metal bond anchor elements 212-214 and 216 are replaced with patterned germanium anchor elements 222-224 and 226, and an aluminum-germanium eutectic bond is applied to bond the active and cap wafers together. To form the MEMS device 13 depicted in FIG. 13, the same fabrication steps as described with reference to FIGS. 2-8 are used, except that, instead of depositing a third metal layer 211 on the top surface of the active wafer structure 200, a layer of germanium is formed on the top surface of the active wafer structure 200. To this end, the top surface of the active wafer structure 200 may be cleaned, and then a layer of germanium may be formed, patterned and etched to form a patterned germanium layer 222, 223, 224, 226 on the active wafer structure 200 prior to etching the active wafer structure 200, as depicted in FIG. 13. The germanium layer may then be patterned and etched using the fourth patterned resist or mask layer (M4) (not shown), thereby defining germanium interconnect structures 223, 224 in the interconnect area, and germanium bond ring structures 222, 226 in the bond ring areas. Once the patterned germanium anchor elements 222-224 and 226 are formed, the fabrication process proceeds to etch the active wafer structure 200 (substantially as shown in FIG. 10) and form the protective cap wafer structure 300 (substantially as shown in FIGS. 11-12). However, rather than using thermocompression techniques, the protective cap wafer structure 300 and active wafer structure 200 are bonded together using an aluminum-germanium eutectic bond under vacuum conditions. The result is shown in FIG. 13 where the germanium bond anchor elements 222-224 and 226 are aligned and bonded to the aluminum anchor elements 312-314 and 316. By attaching the protective cap wafer structure 300 to the active wafer structure 200 using an aluminum-germanium eutectic bond technique, the MEMS transducer structures formed from the active wafer structure 200 can be hermetically sealed by the bonding ring structures 112/202/200a/222/312 and 116/206/200e/226/316.

As will be appreciated, additional or different processing steps may be used to complete the fabrication of the depicted MEMS device structures 1, 13 into functioning devices. In addition to various front end processing steps (such as sacrificial oxide formation, stripping, isolation region formation, implantation, spacer formation, annealing, silicide formation, and polishing steps), additional backend processing steps may be performed, such as forming contact plugs and multiple levels of interconnect(s) that are used to connect the device components in a desired manner to achieve the desired functionality. Thus, the specific sequence of steps used to complete the fabrication of the device components may vary, depending on the process and/or design requirements. It is understood that the terms so used are interchangeable under appropriate circumstances such that the embodiments of the invention described herein are, for example, capable of operation in other orientations than those illustrated or otherwise described herein.

By now, it should be appreciated that there has been provided herein a method for fabricating a MEMS device. In the disclosed methodology, a handle wafer structure is provided that includes a first substrate layer which may be formed with monocrystalline silicon. On a first surface of the first substrate layer, a first patterned metal layer (e.g., aluminum) is formed to define a bottom capacitive sensing electrode, a first interconnect anchor structure, and a first sealing ring structure. In addition, an active wafer structure is provided that includes a second substrate layer (e.g., monocrystalline silicon) and a second patterned metal layer (e.g., aluminum) formed on a first surface of the second substrate layer to define a second interconnect anchor structure and a second sealing ring structure. After placing the active wafer structure on the handle wafer structure to align the first and second interconnect anchor structures and to align the first and second sealing ring structures, the handle wafer structure is bonded to the active wafer structure using metal thermocompression bonding to form a bond between the first and second interconnect anchor structures and between the first and second sealing ring structures. In selected embodiments, the thermocompression bonding is implemented by heating and compressing the handle wafer structure and the active wafer structure so that they are compressed against each other to form the bond between the first and second interconnect anchor structures and between the first and second sealing ring structures. After bonding the handle and active wafer structures, a third patterned layer is formed on a second, opposite surface of the second substrate layer to define a third interconnect anchor structure and a third sealing ring structure. At this point, the active wafer structure may be etched with a deep reactive ion etch process to form a high aspect ratio sensing subassembly from the active wafer structure prior to bonding the cap wafer structure to the active wafer structure. Subsequently, a cap wafer structure is provided that includes a third substrate layer and a fourth patterned metal layer formed on a first surface of the third substrate layer to define an upper capacitive sensing electrode, a fourth interconnect anchor structure and a fourth sealing ring structure. The cap wafer structure is placed on the active wafer structure to align the third and forth interconnect anchor structures and to align the third and fourth sealing ring structures, and the cap wafer structure is then bonded to the active wafer structure to form a bond between the third and fourth interconnect anchor structures and between the third and fourth sealing ring structures, thereby providing a hermetic enclosure surrounding at least part of the active wafer structure. When the third patterned layer is formed as a patterned aluminum layer, the bonding of the cap wafer structure to the active wafer structure may be performed with aluminum-aluminum thermocompression bonding to form a bond between the third and fourth interconnect anchor structures and between the third and fourth sealing ring structures. However, when the third patterned layer is formed as a patterned germanium layer, the bonding of the cap wafer structure to the active wafer structure may be performed with aluminum-germanium eutectic bonding to form a bond between the third and fourth interconnect anchor structures and between the third and fourth sealing ring structures.

In another form, there is provided a method for fabricating a high aspect ratio transducer. In the disclosed methodology, a handle wafer structure (which includes a first out-of-plane sensing electrode on the first surface of the handle wafer structure) is compression bonded to an active wafer structure so that metallic interconnect and anchor elements on a first surface of the handle wafer structure are aligned to corresponding metallic interconnect and anchor elements on a first surface of the active wafer structure. In selected embodiments, the compression bonding process includes heating the handle wafer structure and the active wafer structure, and compressing the handle wafer structure and the active wafer structure against each other to bond the metallic interconnect and anchor elements on the first surface of the handle wafer structure to the corresponding metallic interconnect and anchor elements on the first surface of the active wafer structure. In other embodiments, the handle wafer structure (which includes a first monocrystalline silicon substrate layer and a first patterned aluminum layer that defines the first out-of-plane sensing electrode and the metallic interconnect and anchor elements) is compression bonded to the active wafer structure (which includes a second monocrystalline silicon substrate layer and a second patterned aluminum layer that defines the metallic interconnect and anchor elements on the first surface of the active wafer structure). At this point, the interconnect and anchor elements on the second surface of the active wafer may be formed as metallic (e.g., Al) interconnect and anchor elements that are aligned with the metallic interconnect and anchor elements on the first surface of the active wafer structure. Alternatively, the interconnect and anchor elements on the second surface of the active wafer may be formed as semiconductor (e.g., Ge) interconnect and anchor elements that are aligned with the metallic interconnect and anchor elements on the first surface of the active wafer structure. After the active and handle wafers are bonded, the active wafer structure may be back grinded to a predetermined thickness to allow a high aspect ratio MEMS proof mass element to be formed from the active wafer structure. Subsequently, the active wafer structure is selectively etched to form a high aspect ratio proof mass element which is aligned with the first out-of-plane sensing electrode, and to form semiconductor interconnect and anchor elements which are aligned with the metallic interconnect and anchor elements on the first surface of the active wafer structure. The etch process may be implemented by selectively applying a deep reactive ion etch process to form the high aspect ratio proof mass element and the semiconductor interconnect and anchor elements. Thereafter, a cap wafer structure (which includes a second out-of-plane sensing electrode on the first surface of the cap wafer structure that is aligned with the high aspect ratio proof mass element) is bonded to the active wafer structure so that metallic interconnect and anchor elements on a first surface of the cap wafer structure are aligned to corresponding interconnect and anchor elements on a second surface of the active wafer structure. At this stage, compression bonding can be used to bond the cap wafer structure to the active wafer structure when the interconnect and anchor elements being bonded are all formed with a metallic material. Alternatively, eutectic bonding (e.g., gold and tin eutectic bonding, gold and germanium eutectic bonding, aluminum and germanium cutectic bonding or gold and silicon eutectic bonding) can be used any of the interconnect and anchor elements being bonded are formed with a semiconductor material.

In yet another form, there is provided a high aspect ratio transducer and method for making same. The transducer includes a first monocrystalline semiconductor substrate structure having a first patterned metallic layer that defines a first out-of-plane sensing electrode and one or more metallic interconnect structures on a first surface of the first monocrystalline semiconductor substrate structure. The transducer also includes a second monocrystalline semiconductor substrate structure which includes a second patterned metallic layer, a high aspect ratio proof mass element, and a third patterned metallic or semiconductor layer. The second patterned metallic layer is formed on a first surface of the second monocrystalline semiconductor substrate structure to define one or more metallic interconnect structures that are thermocompression bonded to the one or more metallic interconnect structures on the first surface of the first monocrystalline semiconductor substrate structure. The high aspect ratio proof mass element is formed to be aligned with the first out-of-plane sensing electrode. The third patterned metallic or semiconductor layer is formed on a second surface of the second monocrystalline semiconductor substrate structure to define one or more metallic or semiconductor interconnect structures on the second surface of the second monocrystalline semiconductor substrate structure. Finally, the transducer includes a third monocrystalline semiconductor substrate structure having a fourth patterned metallic layer which defines a second out-of-plane sensing electrode (that is aligned with the high aspect ratio proof mass element) and one or more metallic interconnect structures on a first surface of the third monocrystalline semiconductor substrate structure that are bonded to the one or more metallic or semiconductor interconnect structures on the second surface of the second monocrystalline semiconductor substrate structure.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. While the disclosed MEMS devices may be implemented as a gyroscope, the fabrication process described herein is not limited to gyroscopes or any other type of sensor, but is also applicable to any one of numerous MEMS devices that include some type of structure that is movably suspended by one or more springs and that is formed by bonding an active wafer to a reference wafer. Non-limiting examples of such devices include various types of accelerometers and switches, optical MEMS system components, and other MEMS system devices that use drive and sense electrodes. Thus, the particular embodiments disclosed above are illustrative only and should not be taken as limitations upon the present invention, as the invention may be modified and practiced in different but equivalent manners apparent to those skilled in the art having the benefit of the teachings herein. For example, the methodology of the present invention may be applied using materials other than expressly set forth herein. In addition, the process steps may be performed in an alternative order than what is presented. For example, the sequence of wafer bonding steps may be reversed. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for fabricating a transducer comprising:
providing a handle wafer structure comprising a first substrate layer and a first patterned metal layer formed on a first surface of the first substrate layer to define a bottom capacitive sensing electrode, a first interconnect anchor structure, and a first sealing ring structure;
providing an active wafer structure comprising a second substrate layer and a second patterned metal layer formed on a first surface of the second substrate layer to define a second interconnect anchor structure and a second sealing ring structure;
placing the active wafer structure on the handle wafer structure so that the first and second interconnect anchor structures are aligned and so that the first and second sealing ring structures are aligned;
bonding the handle wafer structure to the active wafer structure using metal thermocompression bonding to form a bond between the first and second interconnect anchor structures and between the first and second sealing ring structures;
forming a third patterned layer on a second, opposite surface of the second substrate layer to define a third interconnect anchor structure and a third sealing ring structure;
providing a cap wafer structure comprising a third substrate layer and a fourth patterned metal layer formed on a first surface of the third substrate layer to define an upper capacitive sensing electrode, a fourth interconnect anchor structure and a fourth sealing ring structure;
placing the cap wafer structure on the active wafer structure so that the third and forth interconnect anchor structures are aligned and so that the third and fourth sealing ring structures are aligned; and
bonding the cap wafer structure to the active wafer structure to form a bond between the third and fourth interconnect anchor structures and between the third and fourth sealing ring structures, thereby providing a hermetic enclosure surrounding at least part of the active wafer structure.

2. The method of claim 1, where providing the handle wafer structure comprises providing a first monocrystalline silicon substrate layer on which is formed a first patterned aluminum layer to define the bottom capacitive sensing electrode, first interconnect anchor structure, and first sealing ring structure.

3. The method of claim 1, where providing the active wafer structure comprises providing a second monocrystalline silicon substrate layer on which is formed a second patterned aluminum layer to define the second interconnect anchor structure and a second sealing ring structure.

4. The method of claim 1, where bonding the handle wafer structure to the active wafer structure comprises:
heating the handle wafer structure and the active wafer structure; and
compressing the handle wafer structure and the active wafer structure against each other to form the bond between the first and second interconnect anchor structures and between the first and second sealing ring structures.

5. The method of claim 1, where forming a third patterned layer comprises forming a patterned aluminum layer on the second, opposite surface of the second substrate layer to define the third interconnect anchor structure and a third sealing ring structure.

6. The method of claim 5, where bonding the cap wafer structure to the active wafer structure comprises aluminum-aluminum thermocompression bonding to form a bond between the third and fourth interconnect anchor structures and between the third and fourth sealing ring structures.

7. The method of claim 1, where forming a third patterned layer comprises forming a patterned germanium layer on the second, opposite surface of the second substrate layer to define the third interconnect anchor structure and a third sealing ring structure.

8. The method of claim 7, where bonding the cap wafer structure to the active wafer structure comprises aluminum-germanium eutectic bonding to form a bond between the third and fourth interconnect anchor structures and between the third and fourth sealing ring structures.

9. The method of claim 1, further comprising etching the active wafer structure with a deep reactive ion etch process to form a high aspect ratio sensing subassembly from the active wafer structure prior to bonding the cap wafer structure to the active wafer structure.

10. A method for fabricating a high aspect ratio transducer, comprising:
compression bonding a handle wafer structure to an active wafer structure so that metallic interconnect and anchor elements on a first surface of the handle wafer structure are aligned to corresponding metallic interconnect and anchor elements on a first surface of the active wafer structure, where the handle wafer structure comprises a first out-of-plane sensing electrode on the first surface of the handle wafer structure;
selectively etching the active wafer structure to form a high aspect ratio proof mass element which is aligned with the first out-of-plane sensing electrode and to form semiconductor interconnect and anchor elements which are aligned with the metallic interconnect and anchor elements on the first surface of the active wafer structure; and
bonding a cap wafer structure to the active wafer structure so that metallic interconnect and anchor elements on a first surface of the cap wafer structure are aligned to corresponding interconnect and anchor elements on a second surface of the active wafer structure, where the cap wafer structure comprises a second out-of-plane sensing electrode on the first surface of the cap wafer structure that is aligned with the high aspect ratio proof mass element.

11. The method of claim 10, where compression bonding the handle wafer structure to the active wafer structure comprises:
heating the handle wafer structure and the active wafer structure; and
compressing the handle wafer structure and the active wafer structure against each other to bond the metallic interconnect and anchor elements on the first surface of the handle wafer structure to the corresponding metallic interconnect and anchor elements on the first surface of the active wafer structure.

12. The method of claim 10, where compression bonding the handle wafer structure to the active wafer structure comprises compression bonding the handle wafer structure comprising a first monocrystalline silicon substrate layer to the active wafer structure comprising a second monocrystalline silicon substrate layer, where a first patterned aluminum layer is formed on the first monocrystalline silicon substrate layer to define the first out-of-plane sensing electrode and the metallic interconnect and anchor elements on the first surface of the handle wafer structure, and where a second patterned aluminum layer is formed on the second monocrystalline silicon substrate layer to define the metallic interconnect and anchor elements on the first surface of the active wafer structure.

13. The method of claim 10, where selectively etching the active wafer structure comprises selectively applying a deep reactive ion etch process to form the high aspect ratio proof mass element and the semiconductor interconnect and anchor elements.

14. The method of claim 10, further comprising forming the corresponding interconnect and anchor elements on the second surface of the active wafer structure as metallic interconnect and anchor elements on the second surface of the active wafer structure that are aligned with the metallic interconnect and anchor elements on the first surface of the active wafer structure prior to selectively etching the active wafer structure.

15. The method of claim 14, where bonding the cap wafer structure to the active wafer structure comprises compression bonding the cap wafer structure to the active wafer structure so that the metallic interconnect and anchor elements on the first surface of the cap wafer structure are aligned with the metallic interconnect and anchor elements on the second surface of the active wafer structure.

16. The method of claim 10, further comprising forming the corresponding interconnect and anchor elements on the second surface of the active wafer as semiconductor interconnect and anchor elements on the second surface of the active wafer structure that are aligned with the metallic interconnect and anchor elements on the first surface of the active wafer structure prior to selectively etching the active wafer structure.

17. The method of claim 16, where bonding the cap wafer structure to the active wafer structure comprises eutectic bonding the cap wafer structure to the active wafer structure so that the metallic interconnect and anchor elements on the first surface of the cap wafer structure are aligned with the semiconductor interconnect and anchor elements on the second surface of the active wafer structure.

18. The method of claim 17, where eutectic bonding comprises gold and tin eutectic bonding, gold and germanium eutectic bonding, aluminum and germanium eutectic bonding or gold and silicon eutectic bonding.

19. The method of claim 10, further comprising back grinding the active wafer structure to a predetermined thickness prior to selectively etching the active wafer structure to allow a high aspect ratio MEMS proof mass element to be formed from the active wafer structure.

20. A high aspect ratio transducer, comprising:
a first monocrystalline semiconductor substrate structure comprising a first patterned metallic layer defining a first out-of-plane sensing electrode and one or more metallic interconnect structures on a first surface of the first monocrystalline semiconductor substrate structure;
a second monocrystalline semiconductor substrate structure comprising:
a second patterned metallic layer on a first surface of the second monocrystalline semiconductor substrate structure defining one or more metallic interconnect structures that are thermocompression bonded to the one or more metallic interconnect structures on the first surface of the first monocrystalline semiconductor substrate structure;
a high aspect ratio proof mass element which is aligned with the first out-of-plane sensing electrode; and
a third patterned metallic or semiconductor layer on a second surface of the second monocrystalline semiconductor substrate structure defining one or more metallic or semiconductor interconnect structures on the second surface of the second monocrystalline semiconductor substrate structure; and
a third monocrystalline semiconductor substrate structure comprising a fourth patterned metallic layer defining a second out-of-plane sensing electrode that is aligned with the high aspect ratio proof mass element and defining one or more metallic interconnect structures on a first surface of the third monocrystalline semiconductor substrate structure that are bonded to the one or more metallic or semiconductor interconnect structures on the second surface of the second monocrystalline semiconductor substrate structure.
